(19) United States
(12) Patent Application Publication
(10) Pub. No.: US 2023/0420424 A1
(43) Pub. Date: Dec. 28, 2023

(54) DISPLAY PANEL AND DISPLAY DEVICE

(71) Applicant: TIANMA ADVANCED DISPLAY TECHNOLOGY INSTITUTE (XIAMEN) CO., LTD., Xiamen (CN)

(72) Inventors: Yingteng ZHAI, Xiamen (CN); Kerui XI, Xiamen (CN); Zhenyu JIA, Xiamen (CN)

(73) Assignee: TIANMA ADVANCED DISPLAY TECHNOLOGY INSTITUTE (XIAMEN) CO., LTD., Xiamen (CN)

(21) Appl. No.: 18/465,188

(22) Filed: Sep. 12, 2023

(30) Foreign Application Priority Data
Jun. 30, 2023 (CN) 202310798312.0

(51) Int. Cl. H01L 25/075; H01L 27/15; H01L 33/38; G09G 3/00

(52) U.S. Cl. CPC H01L 25/0753; H01L 27/156; H01L 33/38; G09G 3/006; G09G 2330/08; G09G 2300/0408

(57) ABSTRACT

A display panel and a display device are provided. The display panel includes a plurality of sub-pixel units. The sub-pixel units include a first sub-pixel unit and a second sub-pixel unit. The first sub-pixel unit is provided with a main electrode and n spare electrodes, and the second sub-pixel unit is provided with a main electrode and m spare electrodes, where n<m, n and m are integers.

This application claims priority to Chinese Patent Application No. 202310798312.0, filed with the China National Intellectual Property Administration on Jun. 30, 2023 and entitled “DISPLAY PANEL AND DISPLAY DEVICE”, which is incorporated herein by reference in its entirety.

### FIELD

The present disclosure relate to the field of display technology, and specifically, to a display panel and a display device.

### BACKGROUND

As an important part of a display device, a display panel is used to realize the display function of the display device. The light-emitting structure of the light-emitting diode (LED) display panel mainly includes electrodes and LED chips, which has low power consumption, high saturation, and a high responding speed, and is widely used in many scenarios.

During the manufacturing process of the LED display panel, it is difficult to prevent the failure of the LED chip, so it is necessary to reserve a spare electrode to reposition the LED chip to repair the display panel. In the display panel, different LED chips have different failure situations, but the arrangement method of the spare electrodes in the conventional technology lacks flexibility for coping with the different failure situations.

### SUMMARY

In order to solve the above problems or at least partly solve the above problems, the present disclosure provides a display panel and a display device.

The present disclosure provides a display panel. The display panel includes sub-pixel units. The sub-pixel units include a first sub-pixel unit and a second sub-pixel unit. The first sub-pixel unit is provided with a main electrode and n spare electrodes, and the second sub-pixel unit is provided with a main electrode and m spare electrodes, where n<m, n and m are integers.

The present disclosure also provides a display device, including the above-mentioned display panel.

### BRIEF DESCRIPTION OF DRAWINGS

The accompanying drawings, which are incorporated in and constitute a part of this specification, illustrate embodiments consistent with the disclosure and together with the description serve to explain the principles of the disclosure.

In order to more clearly illustrate the embodiments of the present disclosure or the prior art, the following will briefly introduce the drawings that need to be used in the description of the embodiments or the prior art.

FIG. 1 shows a schematic diagram of a display panel provided by an embodiment of the present disclosure.

FIG. 2 shows another schematic diagram of a display panel provided by an embodiment of the present disclosure.

FIG. 3 shows another schematic diagram of a display panel provided by an embodiment of the present disclosure.

FIG. 4 shows another schematic diagram of a display panel provided by an embodiment of the present disclosure.

FIG. 5 shows another schematic diagram of a display panel provided by an embodiment of the present disclosure.

FIG. 6 shows another schematic diagram of a display panel provided by an embodiment of the present disclosure.

FIG. 7 shows another schematic diagram of a display panel provided by an embodiment of the present disclosure.

FIG. 8 shows another schematic diagram of a display panel provided by an embodiment of the present disclosure.

FIG. 9 shows another schematic diagram of a display panel provided by an embodiment of the present disclosure;

FIG. 10 shows another schematic diagram of a display panel provided by an embodiment of the present disclosure.

FIG. 11 shows another schematic diagram of a display panel provided by an embodiment of the present disclosure.

FIG. 12 shows another schematic diagram of a display panel provided by an embodiment of the present disclosure.

FIG. 13 shows another schematic diagram of a display panel provided by an embodiment of the present disclosure.

FIG. 14 shows another schematic diagram of a display panel provided by an embodiment of the present disclosure.

FIG. 15 shows another schematic diagram of a display panel provided by an embodiment of the present disclosure.

FIG. 16 shows another schematic diagram of a display panel provided by an embodiment of the present disclosure.

FIG. 17 shows a schematic diagram of a display device provided by an embodiment of the present disclosure.

FIG. 18 shows another schematic diagram of a display device provided by an embodiment of the present disclosure.

FIG. 19 shows a schematic diagram of a first sub-pixel unit in an embodiment of the present disclosure.

FIG. 20 shows a schematic diagram of a second sub-pixel unit in an embodiment of the present disclosure.

### DETAILED DESCRIPTION OF EMBODIMENTS

In order to more clearly understand the embodiments of the present disclosure, the solutions of the present disclosure will be further described below. It should be noted that, in the case of no conflict, the embodiments of the present disclosure and the features in the embodiments can be combined with each other.

In the following description, many specific details are set forth in order to fully understand the present disclosure, but the present disclosure can also be implemented in other ways than described here. Apparently, the embodiments in the description are only some of the embodiments of the present disclosure, and not all examples.

During the manufacturing process of the LED display panel, it is difficult to prevent the failure of the LED chip, so it is necessary to reserve a spare electrode to reposition the LED chip to repair the display panel. In the display panel, different LED chips have different failure situations, but the arrangement methods of the spare electrodes in the conventional technology cannot deal with all the situations.

In view of the above problems, the embodiments of the present disclosure propose a display panel and a display device, including two types of sub-pixel units with different numbers of spare electrodes, to cope with failures in different situations, and solve the problem of inflexible arrangement of spare electrodes in the conventional technology.

The display panel and the display device provided by the embodiments of the present disclosure will be exemplarily described below with reference to the accompanying drawings.

The display panel provided by the embodiment of the present disclosure includes a plurality of sub-pixel units, the sub-pixel units include a first sub-pixel unit and a second sub-pixel unit, and the first sub-pixel unit is provided with a main electrode and n spare electrodes, and the second sub-pixel unit is provided with a main electrode and m spare electrodes, where n<m, n and m are integers. The display panel provided by the embodiments of the present disclosure includes two types of sub-pixel units with different numbers of spare electrodes to cope with failures in different situations. The first sub-pixel unit with a small number of spare electrodes is set at a position with a low repair demand. The second sub-pixel unit with a large number of spare electrodes is arranged at a position with a high repair demand, to solve the problem of inflexible arrangement of spare electrodes in the conventional technology.

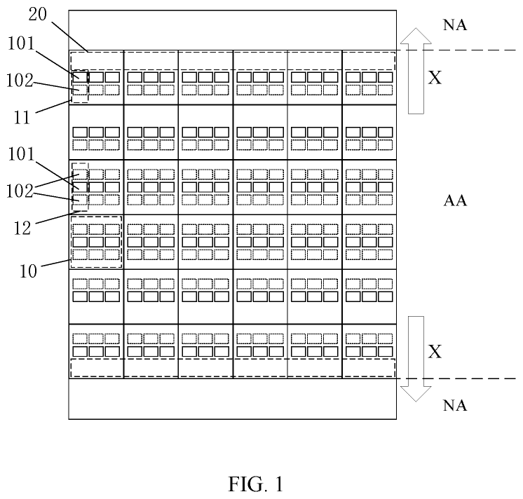

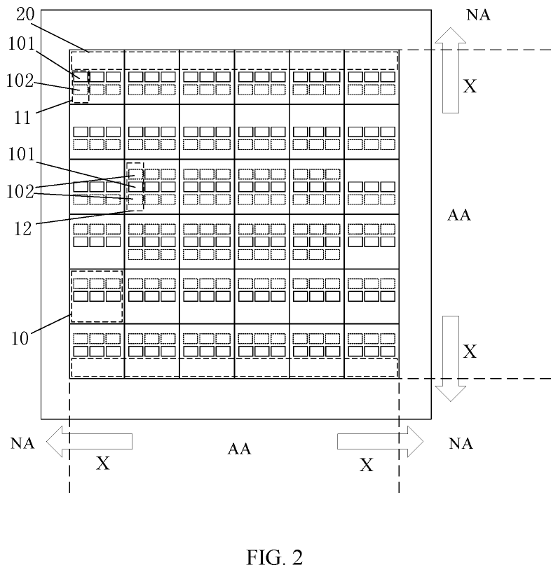

FIG. 1 shows a schematic diagram of a display panel provided by an embodiment of the present disclosure, and FIG. 2 shows another schematic diagram of a display panel provided by an embodiment of the present disclosure. In some embodiments, as shown in FIG. 1 and FIG. 2, the display panel includes a display area AA and a non-display area NA. Along a first direction X, a shortest distance between the first sub-pixel unit 11 and the non-display area NA is smaller than a shortest distance between the second sub-pixel unit 12 and the non-display area NA, and the first direction X is the direction from the display area AA to the non-display area NA. That is, along the first direction X, the first sub-pixel unit 11 is located between the second sub-pixel unit 12 and the non-display area NA. That is, the first sub-pixel unit 11 is closer to the non-display area NA than the second sub-pixel unit 12.

The display panel shown in FIG. 1 includes sub-pixel units, and every three sub-pixel units form a pixel unit 10. The first sub-pixel unit 11 is provided with a main electrode 101 and a spare electrode 102, and the second sub-pixel unit 12 is provided with a main electrode 101 and two spare electrodes 102, that is, n=1, m=2. There is a non-display area NA on the up side of the display area AA and there is another non-display area NA on the low side of the display area AA, and the first direction includes the two directions from the display area AA to the two non-display areas NA. As shown in FIG. 1, along any one of the first directions X, the first sub-pixel unit 11 closest to the non-display area NA is closer to the non-display area NA than the second sub-pixel unit 12 closest to the non-display area NA. That is, the shortest distance between the first sub-pixel unit 11 and the non-display area NA is smaller than the shortest distance between the second sub-pixel unit 12 and the non-display area NA.

In some embodiments, the first sub-pixel unit and the second sub-pixel unit each can be provided with a large number of spare electrodes. For example, n=8, m=10, that is, the first sub-pixel unit is provided with eight spare electrodes, and the second sub-pixel unit is provided with ten spare electrodes. In addition, the difference in the number of spare electrodes corresponding to the second sub-pixel unit and the first sub-pixel unit can be one, two or more, that is, m-n is equal to 1, 2, or a greater value.

It should be noted that the first direction X is not a fixed direction. As shown in FIG. 2, there are four non-display areas NA around the display area AA, and the first direction includes all the four directions from the display area AA to the four non-display areas NA. It can also be seen from FIG. 2 that, along any one of the first directions X, the first sub-pixel unit 11 closest to the non-display area NA is closer to the non-display area NA than the second sub-pixel unit 12 closest to the non-display area NA. That is, the shortest distance between the first sub-pixel unit 11 and the non-display area NA is smaller than the shortest distance between the second sub-pixel unit 12 and the non-display area NA.

In the conventional technology, the arrangement of the spare electrodes in the display panel is inflexible, where the same number of spare electrodes is provided for each sub-pixel unit. For a narrow frame display panel, some side wiring PADs (pads) need to be arranged in the display area, so it is necessary to reserve a space in the display area to arrange the side wiring PADs. The reserved space cannot be used for arranging the sub-pixel units, and thus only a small number of spare electrodes can be arranged in the display panel. Therefore, only one spare electrode is provided for each sub-pixel unit. In this case, only one fault repair can be done for each sub-pixel unit, which reduces the operability of fault repair, and thus reduces the yield rate of the display panel.

The embodiment of the present disclosure includes two kinds of sub-pixel units with different numbers of spare electrodes. The first sub-pixel unit 11 is arranged near the non-display area NA. The first sub-pixel unit 11 is provided with a small number of spare electrodes 102, which can provide the reserved space 20 for arranging the wiring PAD. The second sub-pixel unit 12 is set far away from the non-display area NA, and the second sub-pixel unit 12 is provided with a large number of spare electrodes 102, facilitating fault repairs. Therefore, the operability of fault repairing is greatly improved, and the yield rate of the display panel is improved.

In some embodiments, instead of the situations shown in FIG. 1 and FIG. 2, the non-display areas may be on only one side of the display area, or on three sides of the display area.

In some embodiments, along the first direction X, the first sub-pixel unit 11 is located between the second sub-pixel unit 12 and the non-display area NA. That is, the first sub-pixel unit 11 closest to the non-display area NA is closer to the non-display area NA than the second sub-pixel unit 12 closest to the non-display area NA, and the two types of sub-pixel units can be clearly distinguished, facilitating the repairing operations. If there are non-display areas NA around the display area AA in directions, there will also be first directions X correspondingly, and in each first direction X, the first sub-pixel unit 11 is located between the second sub-pixel unit 12 and the non-display area NA.

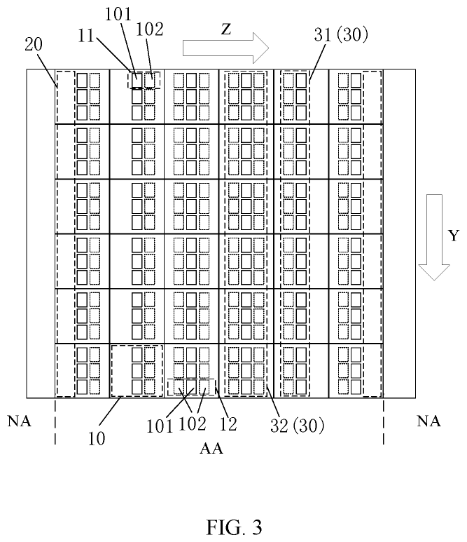

In some embodiments, as shown in FIG. 3, which shows another schematic diagram of a display panel provided by an embodiment of the present disclosure, the display panel includes sub-pixel columns 30, and the sub-pixel columns 30 include sub-pixels. The sub-pixel columns 30 extend along a second direction Y, and are arranged in a third direction Z, and the second direction Y and the third direction Z intersect. FIG. 3 only schematically shows six sub-pixel columns 30 each including sub-pixels. Every three sub-pixel units form a pixel unit 10. The actual display panel includes hundreds to thousands of sub-pixels columns 30, each including hundreds to thousands of sub-pixel units.

As shown in FIG. 3, the vertical direction is the second direction Y, and the horizontal direction is the third direction Z. The sub-pixel column 30 extends along the second direction Y, and also forms sub-pixel rows extending along the third direction Z. The extending direction of the sub-pixel columns 30 intersects the extending direction of the sub-pixel rows. In some other embodiments, the display panel includes sub-pixel rows extending along the second direction Y, and sub-pixel columns 30 extending along the third direction Z, which is equivalent to rotating the FIG. 3 by 90°. In one embodiment, the second direction Y can be a column direction or a row direction.

In some embodiments, the sub-pixel column 30 includes a first-type sub-pixel column 31 and a second-type sub-pixel column 32, the first-type sub-pixel column 31 includes first sub-pixel units 11, and the second-type sub-pixel column 32 includes second sub-pixel units 12. The two sub-pixel columns 30 on the left side and the two sub-pixel columns 30 on the right side in FIG. 3 are the first-type sub-pixel column 31, and all the sub-pixel units in the two sub-pixel columns 30 on the left side and the two sub-pixel columns 30 on the right side are the first sub-pixel units 11 with a small number of spare electrodes 102. The two sub-pixel columns 30 in the middle in FIG. 3 are the second-type sub-pixel columns 32, and all the sub-pixel units in the two sub-pixel columns 30 in the middle are the second sub-pixel units 12 with a large number of spare electrodes 102. In the embodiment of the present disclosure, the sub-pixel units in the same sub-pixel row 30 are of the same type, that is, the sub-pixel units in the same sub-pixel row 30 are provided with the same number of spare electrodes 102, which can facilitate the layout design of the display panel and save production costs.

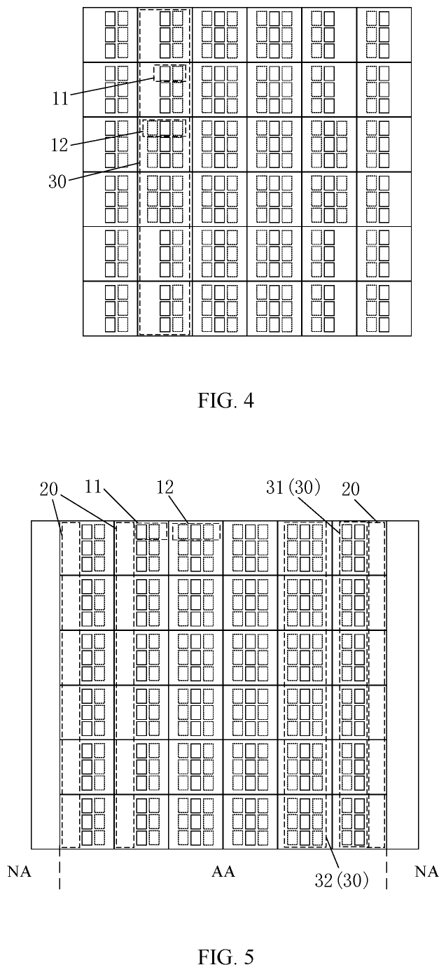

In some embodiments, as shown in FIG. 4, which shows another schematic diagram of a display panel provided by an embodiment of the present disclosure, the same sub-pixel column 30 includes a first sub-pixel unit 11 and a second sub-pixel unit 12. The second pixel column and the fifth pixel column each include both the first sub-pixel unit 11 with a small number of spare electrodes 102 and the second sub-pixel unit 12 with a large number of spare electrodes 102. That is, instead of including the same sub-pixel units, the same sub-pixel column 30 may include sub-pixel units with different numbers of spare electrodes, which can realize number of repair positions for sub-pixels units at different positions of the same sub-pixel column 30, to meeting some layout requirements.

In some embodiments, as shown in FIG. 3, the display panel includes a display area AA and a non-display area NA, and there are at least k columns of first-type sub-pixel columns 31 between the non-display area NA and the second-type sub-pixel columns 32, where k≥2, k is an integer. FIG. 3 shows an example of k=2, that is, there are two first-type sub-pixel columns 31 between the second-type sub-pixel column 32 and the non-display area NA on the left side, and there are also two first-type sub-pixel columns 31 between the second-type sub-pixel column 32 and the non-display area NA on the right side. In some other embodiments, more than three first-type sub-pixel columns 31 are included between the second-type sub-pixel columns 32 and the non-display area NA.

In some embodiments, as shown in FIG. 5, which shows another schematic diagram of the display panel provided by the embodiment of the present disclosure, there are two first-type sub-pixel columns between the second-type sub-pixel column 32 and non-display area NA on the left side, and there is one first-type sub-pixel column 31 between the second-type sub-pixel column 32 and non-display area NA on the right side. Based on the actual needs of some display panels, a small number of side wiring PADs are to be provided on the right side of the display panel, and thus only one first-type sub-pixel columns 31 is arranged on the right side of the display panel to provide the reserved space 20. A large number of side wiring PADs or other circuit structures are to be provided on the left side of the display pane, and thus two first-type sub-pixel columns 31 is arranged on the left side of the display pane to provide the reserved space 20.

In some embodiments, the display panel includes a display area AA and a non-display area NA, and along the third direction Z, the shortest distance between the first-type sub-pixel column 31 and the non-display area NA is smaller than the shortest distance between the second-type sub-pixel column 32 and the non-display area NA. As shown in FIG. 3, the first type of sub-pixel column 31 closest to the non-display area NA is closer to the non-display area NA than the second type of sub-pixel column 32 closest to the non-display area NA, and the reserved space 20 for the wiring PAD or for other circuit structures is in the first-type sub-pixel row 31 that is closer to the non-display area NA.

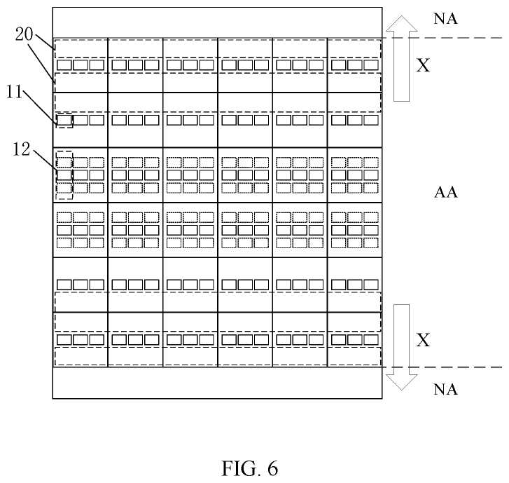

In some embodiments, as shown in FIG. 6, which shows another schematic diagram of a display panel provided by an embodiment of the present disclosure, the first sub-pixel unit 11 has no spare electrode, and the second sub-pixel unit 12 is provided with two spare electrodes, that is, n=0, m=2. Based on the actual needs of some display panels, a large reserved space 20 is provided near the non-display area NA, and no spare electrode is provided for the first sub-pixel unit 11 at this position. When a first sub-pixel unit 11 breaks down, it cannot be repaired, but generally very few first sub-pixel units 11 will fail. Compared with the second sub-pixel unit 12, the first sub-pixel unit 11 being closer to the non-display area NA less affects the overall display function of the display panel. Compared with the foregoing embodiments, the manufacturing cost can be further reduced.

In some embodiments, as shown in FIG. 1 and FIG. 2, the main electrode 101 and the two spare electrodes 102 corresponding to the second sub-pixel unit 12 are arranged along the first direction X, and the two spare electrodes 102 are respectively located at two sides of the main electrode 101. It can be seen from FIG. 1 and FIG. 2 that the two spare electrodes 102 corresponding to the second sub-pixel unit 12 are respectively located on the upper and lower sides of the main electrode 101. A light-emitting unit is placed on each main electrode 101, and the light-emitting unit can be an LED chip. The LED chip includes, but is not limited to, a Mini LED (submillimeter light-emitting diode) chip or a Micro LED (micro light-emitting diode) chip. When the second sub-pixel unit 12 fails, that is, the corresponding light-emitting unit fails, it can be freely chose that whether to use the spare electrode 102 on the upper side to place a repaired light-emitting unit, or use the spare electrode 102 on the lower side to place the repaired light-emitting unit, which improves the operability of the display panel repair.

If the first repair is unsuccessful, a secondary repair can be further carried out. For example, the first repair is to place a repaired light-emitting unit on the spare electrode 102 on the upper side. If the repaired light-emitting unit has a fault, another repaired light-emitting unit can be placed on the spare electrode 102 on the lower side for secondary repair.

In some embodiments, the spare electrode 102 for the first sub-pixel unit 11 is located on a side of the main electrode 101 away from the non-display area NA. When the first sub-pixel unit 11 fails, the spare electrode 102 is used for repair, and the repaired light-emitting unit is placed on the spare electrode 102. In this case, the repaired light-emitting unit can be far away from the non-display area NA and close to the center of the display area AA, and the overall display effect of the display panel is more compact.

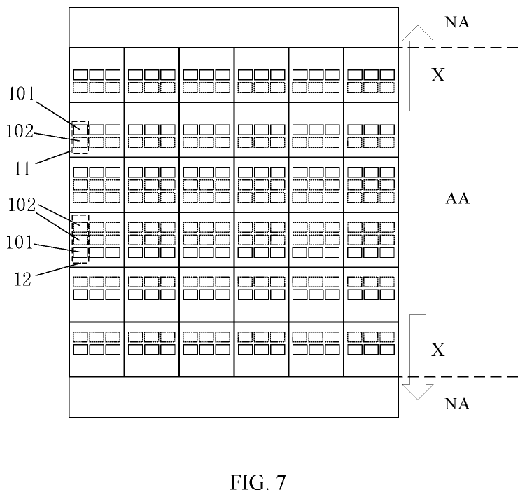

In some embodiments, as shown in FIG. 7, which shows another schematic diagram of the display panel provided by the embodiment of the present disclosure, the two spare electrodes for the second sub-pixel unit 12 are located on the same side of the main electrode. When second sub-pixel units 12 fail, the spare electrodes on the same side are used for repairing, thus ensuring the consistency of the display effect after repairing.

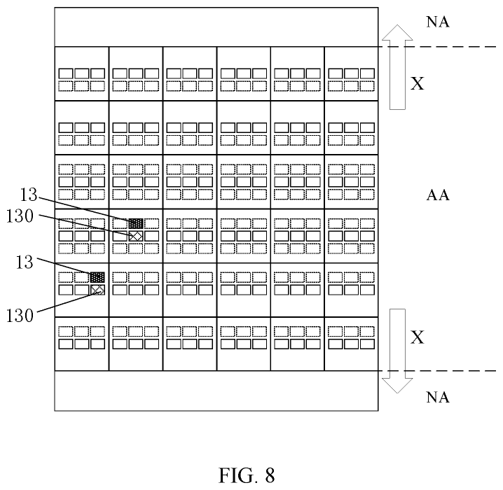

In some embodiments, as shown in FIG. 8, which shows another schematic diagram of a display panel provided by an embodiment of the present disclosure, a repaired light-emitting unit 13 is placed on the spare electrode on the side, away from the non-display area NA, of the main electrode for at least one sub-pixel unit. A light-emitting unit is placed on the main electrode, and when the light-emitting unit is damaged or missing, it becomes a faulty light-emitting unit 130. When repairing the faulty light-emitting unit 130, in some embodiments, the damaged light-emitting unit on the main electrode is kept, and the repaired light-emitting unit 13 is directly placed on the corresponding spare electrode. In one embodiment, the damaged light-emitting unit on the main electrode is removed by laser, and the main electrode has no light-emitting unit thereon, and then the repaired light-emitting unit 13 is placed on the corresponding spare electrode.

FIG. 8 shows two faulty light emitting units 130, one of which is in the first sub-pixel unit and the other is in the second sub-pixel unit. After repairing the two faulty light emitting units 130, the two repaired light-emitting units 13 are both placed on the spare electrodes on the sides of the main electrodes away from the non-display area NA, and the repaired light-emitting units 13 are close to the center of the display area AA, making the overall display effect of the display panel very compact after the repair.

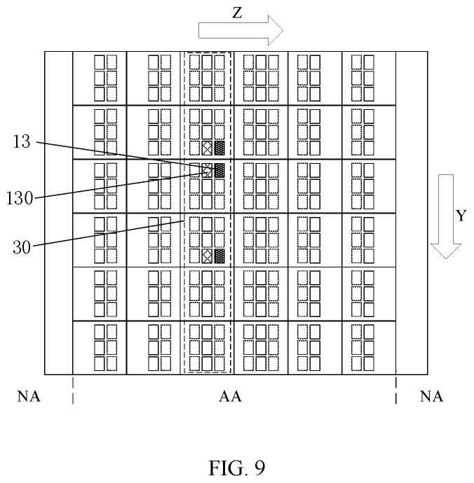

In some embodiments, as shown in FIG. 9, which shows another schematic diagram of a display panel provided by an embodiment of the present disclosure, repaired light-emitting units 13 are placed on the spare electrodes on the same side of the main electrodes for some sub-pixel units in the same sub-pixel column 30. FIG. 9 shows three faulty light emitting units 130 located in the same sub-pixel column 30. After the three faulty light-emitting units 130 are repaired, three repaired light-emitting units 13 are all placed on the spare electrodes on the side of the main electrodes away from the non-display area NA, which ensures the consistency of the display effect after repair. Furthermore, the three repaired light-emitting units 13 are closer to the center of the display area AA, and the overall display effect of the display panel is more compact after the repair.

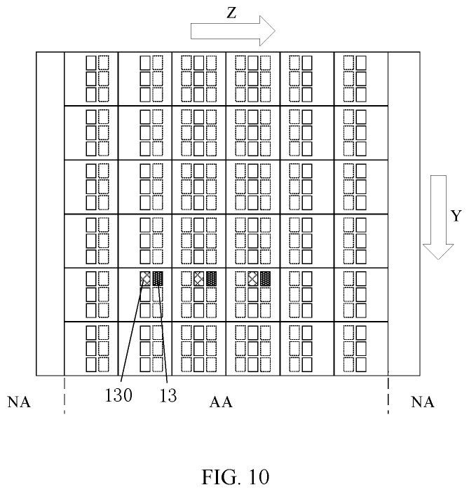

In some embodiments, as shown in FIG. 10, which shows another schematic diagram of a display panel provided by an embodiment of the present disclosure, three faulty light emitting units 130 are located in the same sub-pixel row. After repairing the three faulty light-emitting units 130, three repaired light-emitting units 13 are all placed on the spare electrodes on the same side of the main electrodes, which ensures the consistency of the display effect after the repair.

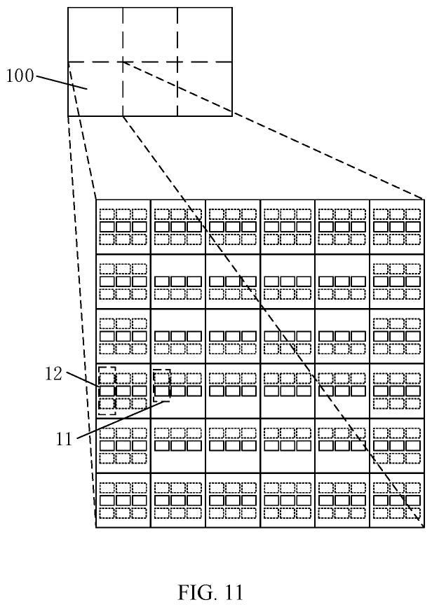

In some embodiments, as shown in FIG. 11, which shows another schematic diagram of a display panel provided by an embodiment of the present disclosure, the display panel includes transferring stamp partitions 100, and the transferring stamp partition 100 includes multiple first sub-pixel units 11 and multiple second sub-pixel units 12. In the transferring stamp partition 100, the shortest distance between the first sub-pixel unit 11 and an adjacent transferring stamp partition 100 is greater than the shortest distance between the second sub-pixel unit 12 and the adjacent transferring stamp partition 100.

In the manufacturing process of a display panel, light-emitting units (such as LED chips) are grown on a wafer, and then the light-emitting units are peeled off from the wafer and placed on a temporary substrate, and then the light-emitting units are picked up from the temporary substrate in batches by using a transferring stamp (transferring head), and transferred to the display panel, which is the display panel shown in FIG. 11 prepared with the main electrodes and the spare electrodes. The size of the transferring stamp is usually smaller than the display panel, so the display panel can be divided into several transferring stamp partitions 100. The display panel in FIG. 11 is divided into six transferring stamp partitions 100, and the transferring stamp transfers the light-emitting units in one transferring stamp partition 100 each time.

FIG. 11 also shows the distribution of the first sub-pixel units 11 and the second sub-pixel units 12 in each transferring stamp partition 100, the first sub-pixel unit 11 closest to the adjacent transferring stamp partition 100 is closer to the adjacent transferring stamp partition 100 than the second sub-pixel unit 12 closest to the adjacent transferring stamp partition 100. That is, the shortest distance between the first sub-pixel unit 11 and the adjacent transferring stamp partition 100 is greater than the shortest distance between the second sub-pixel unit 12 and the adjacent transferring stamp partition 100, which forms a distribution that the second sub-pixel units 12 surround the first sub-pixel units 11.

In the process of using the transferring stamp to transfer the light-emitting units, the yield rate of the light-emitting units located at the edge of the transferring stamp is lower than that of the light-emitting units located in the middle of the transferring stamp. Therefore, in a transferring stamp partition 100, the first sub-pixel units 11 with less spare electrodes is arranged in the middle position, and the second sub-pixel units 12 with more spare electrodes is arranged at the edge position, facilitating multiple times of fault repair and thus improving the overall yield of the display panel.

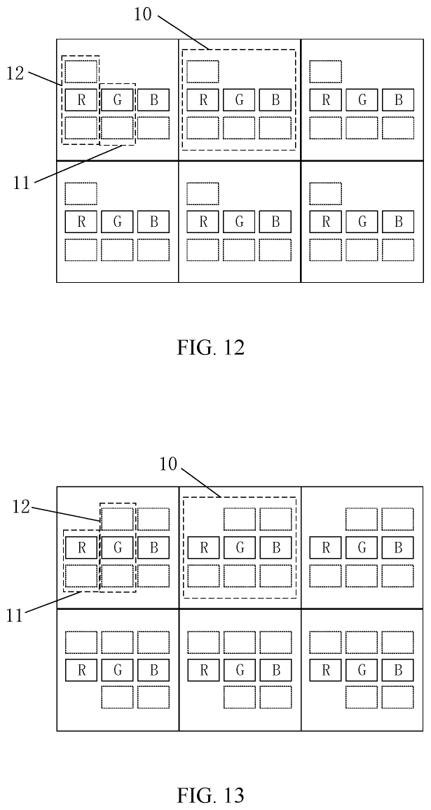

In some embodiments, as shown in FIG. 12, which shows another schematic diagram of a display panel provided by an embodiment of the present disclosure, a blue light-emitting unit or a green light-emitting unit is placed on the main electrode of the first sub-pixel unit 11, and a red light-emitting unit is placed on the main electrode of the second sub-pixel unit 12. As shown in FIG. 12, every three sub-pixel units of different colors form a pixel unit 10, and the three sub-pixel units are usually red (R), green (G), and blue (B). Because the light-emitting units of different colors have different luminous efficiency. The red light-emitting unit needs surface roughening to improve the luminous efficiency, which causes that the transfer yield of the red light-emitting unit is lower than that of the other two light-emitting units. Therefore, the red sub-pixel unit is set as the second sub-pixel unit 12 with a large number of spare electrodes, so as to repair more faults and improve the overall yield of the display panel.

In some embodiments, as shown in FIG. 13, which shows another schematic diagram of a display panel provided by an embodiment of the present disclosure, a red light-emitting unit is placed on the main electrode corresponding to the first sub-pixel unit 11, and a blue light-emitting unit or a green light-emitting unit is placed on the main electrode corresponding to the second sub-pixel unit 12. The size of the red light-emitting unit is larger than that of the blue light-emitting unit and the green light-emitting unit. As shown in FIG. 13, every three sub-pixel units of different colors form a pixel unit 10, and the three sub-pixel units are usually red (R), green (G), and blue (B). Because the luminous efficiency of the red light-emitting unit is relatively low, the red light-emitting unit is made larger than the green light-emitting unit and blue light-emitting unit. In this case, during the transfer process of light-emitting units, the transfer yield of small green light-emitting units and blue light-emitting units is lower than that of red light-emitting units. Therefore, the green sub-pixel units and blue sub-pixel units are set as the second sub-pixel unit 12 with more spare electrodes, so as to repair more faults and improve the overall yield of the display panel.

In some embodiments, the number of the first sub-pixel units 11 is less than or equal to the number of the second sub-pixel units 12. In order to improve the overall yield of the display panel, it is necessary to provide more operability for fault repair, so the second sub-pixel units 12 with more spare electrodes needs to be made as many as possible to increase the total number of spare electrodes in the display panel.

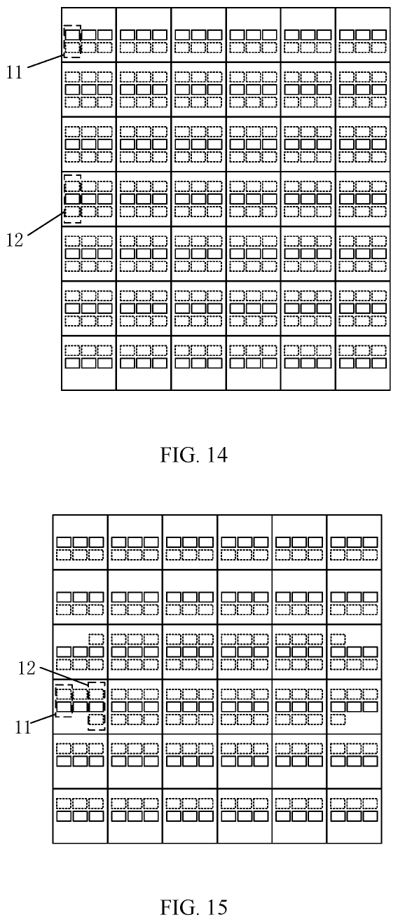

In some embodiments, as shown in FIG. 14, which shows another schematic diagram of a display panel provided by an embodiment of the present disclosure, the number of first sub-pixel units 11 is N, and the number of second sub-pixel units 12 is M, where (M−N)/M>50%. In this way, the number of the second sub-pixel unit 12 is far greater than the number of the first sub-pixel unit 11, so as to provide enough spare electrodes to ensure the overall yield of the display panel.

In some embodiments, as shown in FIG. 15, which is another schematic diagram of a display panel provided by an embodiment of the present disclosure, the number of second sub-pixel units 12 is smaller than the number of first sub-pixel units 11. In order to reduce the manufacturing cost of the display panel, the total amount of spare electrodes should be appropriately reduced. Therefore, more first sub-pixel units 11 and less second sub-pixel units 12 are provided. That is, the number of first sub-pixel units 11 is greater than the number of the second sub-pixel units 12.

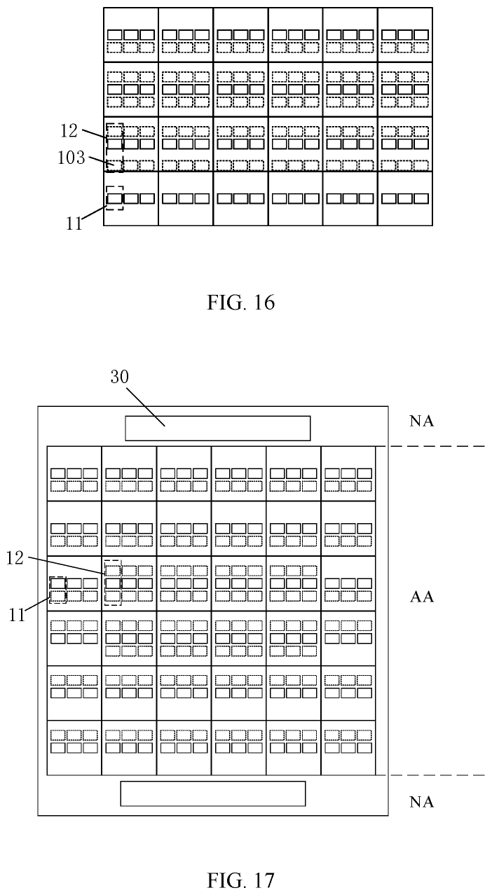

In some embodiments, as shown in FIG. 16, which is another schematic diagram of a display panel provided by an embodiment of the present disclosure, at least a part of the first sub-pixel units 11 and the second sub-pixel units 12 share spare electrodes. The position of a common spare electrode 103 is close to the middle position between the first sub-pixel unit 11 and the second sub-pixel unit 12, which means that the first sub-pixel unit 11 is not provided with a spare electrode, and one of the spare electrodes of the second sub-pixel units 12 is arranged very close to the first sub-pixel unit 11. When the light-emitting unit on the main electrode of the second sub-pixel unit 12 fails, or the light-emitting unit on the main electrode of the first sub-pixel unit 11 fails, the common spare electrode 103 can be used for repair. By arranging the common spare electrodes, a larger space for arranging wiring PAD or other circuit structures can be reserved from the first sub-pixel units 11.

An embodiment of the present disclosure further provides a display device, including the display panel provided by any one of the foregoing embodiments of the present disclosure. The display device provided by the embodiment of the present disclosure includes two types of sub-pixel units with different numbers of spare electrodes to cope with failures in different situations. The first sub-pixel unit 11 with a small number of spare electrodes is installed at a position with a low repair demand. The second sub-pixel unit 12 with a large number of spare electrodes is arranged at a position with a high repair demand, to solve the technical problem of inflexible arrangement of spare electrodes in the conventional technology.

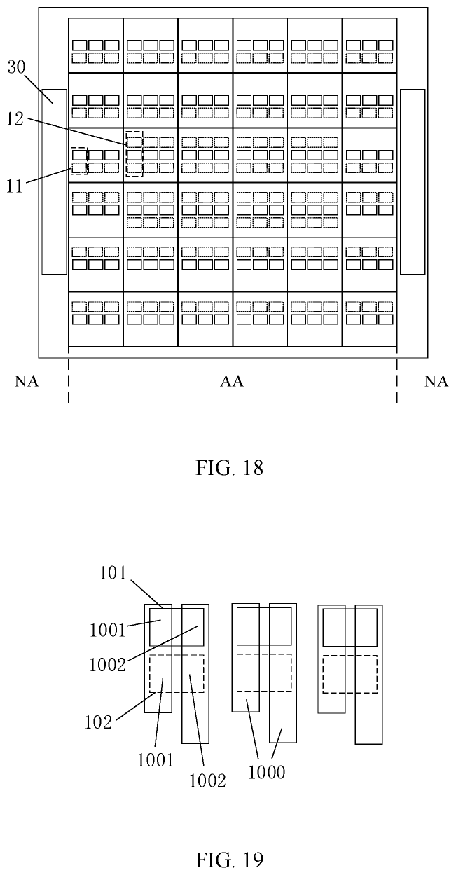

FIG. 17 shows a schematic diagram of a display device provided by an embodiment of the present disclosure, and FIG. 18 shows another schematic diagram of a display device provided by an embodiment of the present disclosure. In some embodiments, as shown in FIG. 17 and FIG. 18, the display device further includes a driving chip 30, the distance between at least one first sub-pixel unit 11 and the driving chip 30 is smaller than the distance between at least one second sub-pixel unit 12 and the driving chip 30.

The number of the driver chip 30 can be one or more. The display device in FIG. 17 includes two driver chips 30, and the two driver chips 30 are arranged in the non-display area NA on the upper side and the lower side of the display panel. The display device in FIG. 18 also includes two driving chips 30, and the two driving chips 30 are arranged in the non-display area NA on the left and right sides of the display panel. The first sub-pixel unit 11 closest to the driving chip 30 is closer to the driving chip 30 than the second sub-pixel unit 12 closest to the driving chip 30, and is used to provide the reserved space for wiring PAD or other circuit structures. The first sub-pixel unit 11 is located closer to the driving chip 30, which facilitates signal transmission between the driving chip 30 and circuit structures such as wiring PAD.

In some embodiments, the display device is a Micro-LED (miniature light-emitting diode) display device, and the size of the light-emitting unit can reach a micron level.

In some embodiments, the display device can be a narrow-frame display device, such as a large commercial spliced screen applied in a public place, with a total height and width of several meters. This type of large display screen is spliced by small display devices. By using narrow-frame display devices for splicing, the image will not appear obvious splits at the seams of the large display screen, which improves the display effect of the large display screen.

The display panel provided by the embodiments of the present disclosure includes two types of sub-pixel units with different numbers of spare electrodes to cope with failures in different situations. The first sub-pixel unit with a small number of spare electrodes is set at a position with a low repair demand. The second sub-pixel unit with a large number of spare electrodes is arranged at a position with a high repair demand, to solve the technical problem of inflexible arrangement of spare electrodes in the conventional technology.

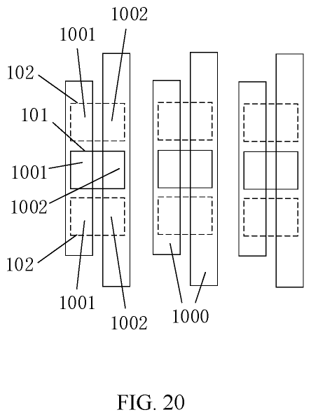

As shown in FIG. 19 and FIG. 20, the main electrode 101 and the spare electrode 102 described in the above embodiments of the present disclosure both include an anode 1001 and a cathode 1002 for connecting with a light emitting unit. That is, the main electrode 101 includes an anode 1001 and a cathode 1002, and the spare electrode 102 also includes an anode 1001 and a cathode 1002. Anodes 1001 (the anode of the main electrode and the anode of the spare electrode) corresponding to one sub-pixel unit can be made into a metal electrode strip 1000. Similarly, cathodes 1002 (the cathode of the main electrode and the cathode of the spare electrode) can be made into a metal electrode strip 1000.

It should be noted that in this article, relative terms such as “first” and “second” are only used to distinguish one entity or operation from another entity or operation, and do not necessarily require or imply these such actual relationship or order exists between entities or operations. Furthermore, the term “comprises”, “comprises” or any other variation thereof is intended to cover a non-exclusive inclusion and a process, method, article, or apparatus comprising a set of elements includes not only those elements, but also includes elements not expressly listed, other elements of or also include elements inherent in such a process, method, article, or device. Without further limitations, an element defined by the phrase “comprising a . . . ” does not exclude the presence of additional identical elements in the process, method, article or apparatus comprising said element.

1. A display panel, comprising:
a plurality of sub-pixel units, wherein the sub-pixel units comprises a first sub-pixel unit and a second sub-pixel unit; the first sub-pixel unit is provided with a main electrode and n spare electrodes; the second sub-pixel unit is provided with a main electrode and m spare electrodes; n<m, n and m are integers.

2. The display panel according to claim 1, further comprising a display area and a non-display area, wherein along a first direction, a shortest distance between the first sub-pixel unit and the non-display area is smaller than a shortest distance between the second sub-pixel unit and the non-display area, the first direction is a direction from the display area to the non-display area.

3. The display panel according to claim 2, wherein the first sub-pixel unit is located between the second sub-pixel unit and the non-display area along the first direction.

4. The display panel according to claim 1, wherein the display panel comprises a plurality of sub-pixel columns each comprising a plurality of sub-pixels, the plurality of sub-pixel columns extend along a second direction and are arranged in a third direction, and the second direction and the third direction intersect.

5. The display panel according to claim 4, wherein at least one of the plurality of sub-pixel columns comprises the first sub-pixel unit and the second sub-pixel unit.

6. The display panel according to claim 4, wherein the plurality of sub-pixel columns comprise a first-type sub-pixel column and a second-type sub-pixel column, the first-type sub-pixel column comprises a plurality of the first sub-pixel units, and the second-type sub-pixel column comprises a plurality of the second sub-pixel units.

7. The display panel according to claim 6, further comprising a display area and a non-display area, wherein at least k first-type sub-pixel columns are located between the non-display area and the second type of sub-pixel columns k≥2, k is an integer.

8. The display panel according to claim 6, further comprising a display area and a non-display area, wherein along the third direction, a shortest distance between the first-type sub-pixel column and the non-display area is shorter than the shortest distance between the second-type sub-pixel column and the non-display area.

9. The display panel according to claim 2, wherein the first sub-pixel unit is provided with one spare electrode, the second sub-pixel unit is provided with two spare electrodes.

10. The display panel according to claim 9, wherein the main electrode and the two spare electrodes provided for the second sub-pixel unit are arranged along the first direction, and the two spare electrodes are respectively located on two sides of the main electrode.

11. The display panel according to claim 9, wherein the spare electrode provided for the first sub-pixel unit is located on a side of the main electrode away from the non-display area.

12. The display panel according to claim 10, wherein a repaired light-emitting unit is placed on the spare electrode on the side, away from the non-display area, of the main electrode provided for at least one of the sub-pixel units.

13. The display panel according to claim 4, wherein a plurality of repaired light-emitting units are placed on a plurality of spare electrodes on a same side of the main electrodes provided for at least a part of the sub-pixel units in a same sub-pixel column.

14. The display panel according to claim 1, further comprising a plurality of transferring stamp partitions, and at least one of the plurality of transferring stamp partitions comprises a plurality of the first sub-pixel units and a plurality of the second sub-pixel units, a shortest distance between the first sub-pixel units and an adjacent transferring stamp partition is greater than a shortest distance between the second sub-pixel units and an adjacent transferring stamp partition.

15. The display panel according to claim 1, wherein a blue light-emitting unit or a green light-emitting unit is placed on the main electrode provided for the first sub-pixel unit, and a red light-emitting unit is placed on the main electrode provided for the second sub-pixel unit.

16. The display panel according to claim 1, wherein a red light-emitting unit is placed on the main electrode provided for the first sub-pixel unit, and a blue light-emitting unit or a green light-emitting unit is placed on the main electrode provided for the second sub-pixel unit, a size of the red light-emitting unit is larger than a size of the blue emitting unit or the green emitting unit.

17. The display panel according to claim 1, wherein
a number of the first sub-pixel unit is less than or equal to a number of the second sub-pixel unit; or
a number of the second sub-pixel unit is less than a number of the first sub-pixel unit.

18. The display panel according to claim 1, wherein the first sub-pixel unit and the second sub-pixel unit share a spare electrode.

19. A display device, comprising:
a display panel, wherein the display panel comprises a plurality of sub-pixel units, wherein the sub-pixel units comprise a first sub-pixel unit and a second sub-pixel unit, the first sub-pixel unit is provided with a main electrode and n spare electrodes; the second sub-pixel unit is provided with a main electrode and m spare electrodes, n<m, n and m are integers.

20. The display device according to claim 19, further comprising a driving chip, a distance between the first sub-pixel unit and the driving chip is smaller than a distance between the second sub-pixel unit and the driving chip.
